(19) United States
(12) Patent Application Publication
(10) Pub. No.: US 2025/0380551 A1
(43) Pub. Date: Dec. 11, 2025

(54) DISPLAY DEVICE AND METHOD FOR MANUFACTURING THE SAME

(71) Applicant: LG Display Co., Ltd., Seoul (KR)

(72) Inventors: Tae Yoon KIM, Paju-si (KR); Hye Sun JUNG, Paju-si (KR); Bung Goo KIM, Paju-si (KR); Hyoung Ho AHN, Paju-si (KR); Hee Won LEE, Paju-si (KR); Jun Young JO, Paju-si (KR)

(73) Assignee: LG Display Co., Ltd., Seoul (KR)

(21) Appl. No.: 19/233,889

(22) Filed: Jun. 10, 2025

(30) Foreign Application Priority Data
Jun. 11, 2024 (KR) 10-2024-0075487

(51) Int. Cl. H10H 29/49; H10H 29/01; H10H 29/856

(52) U.S. Cl. CPC H10H 29/49; H10H 29/012; H10H 29/856

(57) ABSTRACT

Embodiments of the present disclosure provides a display device including a substrate having a display area and a non-display area. A driver is positioned in the display area, and a plurality of pixels connected to the driver. Each pixel of the plurality of pixels includes a plurality of sub-pixels, and each sub-pixel includes a light-emitting element positioned in an emission area. A connection electrode is configured to connect the light-emitting element to the driver. A first electrode is positioned between the light-emitting element and the connection electrode. A protective layer is positioned between one end of the first electrode and the connection electrode. Also disclosed is a method of manufacturing the display device, which includes forming the connection electrode with multiple metal layers, exposing a reflective region of the electrode, forming a protective layer with an opening, and positioning the first electrode in the reflective region.

### CROSS-REFERENCE TO RELATED APPLICATION

This application claims priority to and the benefit of Korean Patent Application No. 10-2024-0075487, filed Jun. 11, 2024, the disclosure of which is incorporated herein by reference in its entirety.

### BACKGROUND

### Technical Field

The present disclosure relates to a display device and a method for manufacturing the same. More specifically, it relates to a display device and a method for manufacturing the same, which can reduce costs and defects by efficiently transferring light-emitting elements of the display device.

### Description of the Related Art

A liquid crystal display device and an organic light-emitting display device have been used as a flat panel display device.

The organic light-emitting display device has advantages such as improved luminous efficiency, fast response speed, and a wide viewing angle, compared to the liquid crystal display device. However, the organic light-emitting display device still has low luminous efficiency and may suffer from reduced reliability and lifespan due to its vulnerability to moisture, as it includes an organic material.

Recently, a micro light-emitting diode display device, which is an inorganic light-emitting display device, has been proposed.

The micro light-emitting diode display device implements an image by arranging inorganic light-emitting elements, each having a size of 100 micrometers (μm) or less, in respective pixels. In the micro light-emitting diode display device, a driving circuit may be formed on an array substrate, and micro light-emitting elements may be arranged on the array substrate and electrically connected to the driving circuit.

### BRIEF SUMMARY

The disclosed display device and manufacturing method improve yield, efficiency, and reliability by addressing challenges in micro light emitting diode transfer alignment and bonding. One of the features is the use of a multilayer connection electrode that includes a selectively exposed reflective layer to enhance light emission. The design incorporates enlarged adhesive regions that maintain bonding integrity even when micro light emitting diodes are slightly misaligned during transfer. A transparent electrode, combined with bonding through a eutectic process using two separate adhesive layers, ensures strong electrical and mechanical connections.

Additional features include a protective layer that covers the edges of the connection electrode to prevent damage during processing, and a pixel structure that includes multiple sub-pixels with redundant light emitting elements. A light blocking layer with controlled transmission openings compensates for any defective elements and improves display uniformity. The pixel layout is suitable for high resolution applications and is compatible with flexible substrates and a wide range of materials. These features support improved manufacturing tolerance, enhanced optical performance, and greater structural reliability.

In order to drive the micro light-emitting element on the substrate of the display device, a thin-film transistor may be formed on the substrate and electrically connected to the micro light-emitting element, or a driving circuit chip may be mounted on the substrate and electrically connected to the micro light-emitting element.

The display device may be formed by electrically connecting the thin-film transistor or the driving circuit chip to the micro light-emitting element through connection wires.

During a process of transferring the micro light-emitting element onto the substrate, the micro light-emitting element may not be positioned at a designated location.

Various embodiments of the present disclosure provide a display device and a method for manufacturing the same, which allow the display device to operate even when some micro light-emitting elements are misaligned.

The technical problems to be solved by embodiments of the present disclosure are not limited to those mentioned above, and other problems not specifically mentioned herein will be clearly understood by those of ordinary skill in the art from the following description.

A display device according to embodiments of the present disclosure may include: a substrate including a display area and a non-display area; a driver positioned in the display area; a plurality of pixels connected to the driver, each of the plurality of pixels including a plurality of sub-pixels; a light-emitting element positioned in an emission area of the sub-pixel; a connection electrode configured to connect the light-emitting element to the driver; a first electrode positioned between the light-emitting element and the connection electrode; and a protective layer positioned between one end of the first connection electrode and the connection electrode.

A method for manufacturing a display device according to embodiments of the present disclosure may include: positioning a driver in a display area including a plurality of pixels on a substrate; positioning a first insulating layer on the driver; forming, on the first insulating layer, a connection electrode connected to the driver and including a plurality of metal layers and a reflective layer; forming a reflective region by removing at least one layer among the plurality of metal layers of the connection electrode to expose the reflective layer; positioning a protective layer on the connection electrode and the first insulating layer; forming an opening in the protective layer to expose the reflective region; and positioning a first electrode in the reflective region.

According to embodiments of the present disclosure, transfer process defects of micro light-emitting elements in the display device may be reduced.

According to embodiments of the present disclosure, the transfer efficiency of micro light-emitting elements may be improved, thereby reducing manufacturing and component costs.

The effects of the present disclosure are not limited to those mentioned above, and other effects not explicitly described will be clearly understood by those skilled in the art from the following description.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a plan view illustrating a display device according to one embodiment of the present disclosure;

FIG. 2 is an enlarged plan view of a region A in FIG. 1;

FIG. 3 is an enlarged plan view of a region of a pixel PXL in FIG. 2;

FIG. 4 is a cross-sectional view taken along line 4-4′ in FIG. 3;

FIGS. 5A to 5F are cross-sectional views illustrating manufacturing processes of a region of a pixel PXL in FIG. 4 according to one embodiment of the present disclosure;

FIG. 6 is a schematic cross-sectional view of a region of a pixel PXL in FIG. 4 according to one embodiment of the present disclosure; and

FIG. 7 is a schematic plan view of a region of a pixel PXL of a display device according to another embodiment of the present disclosure.

### DETAILED DESCRIPTION

The advantages and features of the present disclosure, and methods of achieving them will be apparent from the embodiments described in detail below in conjunction with the accompanying drawings. However, the present disclosure is not limited to the following embodiments, but may be implemented in various different forms; rather, the present embodiments are provided to make the description of the present disclosure complete and to allow those skilled in the art to fully understand the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Identical reference numerals may designate identical components throughout the description. Further, in describing the present disclosure, detailed descriptions of known related technologies may be omitted if it is considered to unnecessarily obscure the gist of the present disclosure. The terms such as “including,” “having,” and “consisting of” used herein are generally intended to allow other components to be added unless the terms are used with the term “only.” References to components of a singular noun include the plural of that noun, unless specifically stated otherwise.

In interpreting components, they are construed to include a margin of error, even if it is not explicitly stated.

When describing a positional relationship, for example, “on,” “above,” “below,” or “next to” describes the positional relationship of two parts, one or more other parts may be located between the two parts, unless “immediately” or “directly” is used.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Although a first, a second,” etc., are used to describe various components, these components are not limited by these terms. These terms are used only to distinguish one component from another. Therefore, the first component referred to below may be a second component within the technical spirit of the present disclosure.

Each of the features of various embodiments of the present disclosure may be coupled or combined with one another in whole or in part, and may be technologically interlocked and operated in various ways, as will be appreciated by those skilled in the art, and each of the embodiments may be carried out independently or in conjunction with one another.

Hereinafter, a display device according to embodiments of the present disclosure will be described in detail with reference to the accompanying drawings.

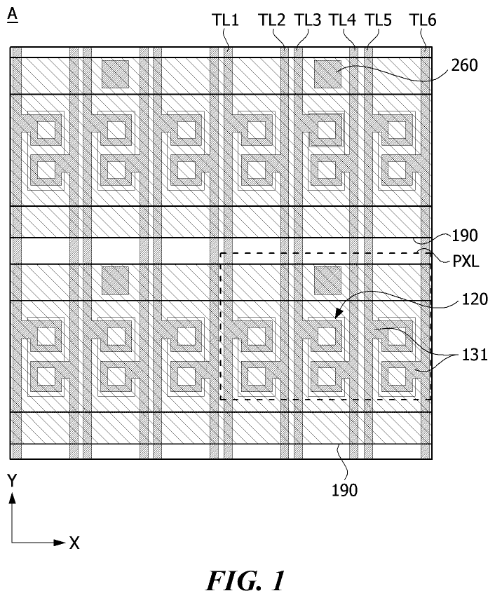

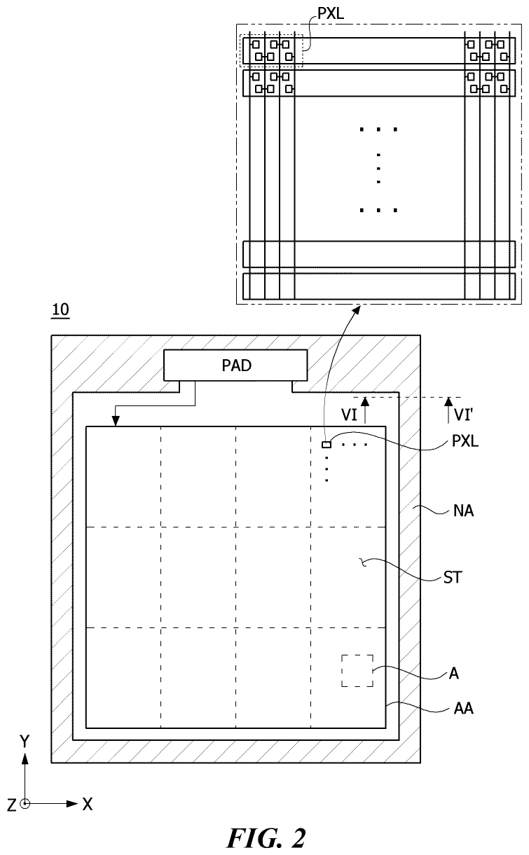

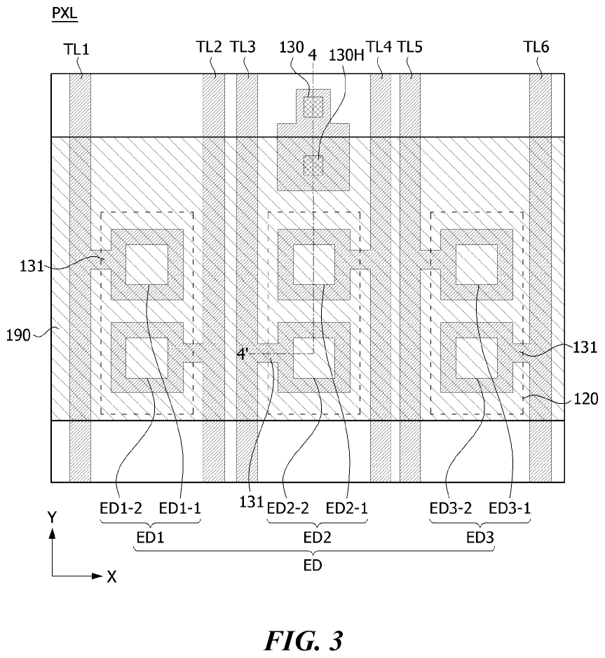

FIG. 1 is a plan view illustrating a display apparatus according to one embodiment of the present disclosure. FIG. 2 is an enlarged view of a region A in FIG. 1. FIG. 3 is an enlarged view of a region PXL in FIG. 2.

Referring to FIGS. 1 and 2, a display device 10 according to an embodiment of the present disclosure includes a display panel. The display panel may include a display area AA in which an image is displayed and a non-display area NA in which no image is displayed. In the non-display area NA, various wires and driving circuits may be mounted and a pad part PAD may be disposed to which integrated circuits, printed circuits, etc., are connected.

A plurality of light-emitting elements ED arranged in the display area AA to form a pixel PXL may be micro-sized inorganic light-emitting elements. The inorganic light-emitting elements may be grown on a silicon wafer and then attached to the display panel through a transfer process.

The transfer process of the light-emitting elements ED may be performed for each pre-divided region. In FIG. 1, the display area AA is shown as being divided into twelve transfer regions ST, but the size or the number of divisions of the transfer regions is not limited thereto. The transfer process may be sequentially or simultaneously performed for first to twelfth transfer regions ST.

A blue light-emitting element ED1, a green light-emitting element ED2, and a red light-emitting element ED3 may be sequentially transferred to a transfer region ST.

In the non-display area NA, a data driving circuit or a gate driving circuit may be arranged and wires through which a control signal and the controlling the driving circuits is supplied may be disposed. Here, the control signal may include various timing signals including a clock signal, an input data enable signal, and synchronization signals, and may be received through the pad part PAD.

The pixels PXL may be driven by the pixel driving circuit. The pixel driving circuit may receive a driving voltage, an image signal (digital signal), a synchronization signal synchronized with the image signal, and the like, and may output an anode voltage and a cathode voltage of the light-emitting element ED to drive the plurality of pixels PXL. The driving voltage may be a high potential voltage. The cathode voltage may be a low potential voltage commonly applied to the pixels PXL. The anode voltage may be a voltage corresponding to a pixel data value of the image signal. The pixel driving circuit may be disposed in the non-display area NA, or may be disposed below the display area AA.

Each of the pixels PXL may include a plurality of sub-pixels having different colors. For example, the plurality of pixels PXL may include a red sub-pixel in which the light-emitting element ED1 that emits light of a red wavelength is disposed, a green sub-pixel in which the light-emitting element ED2 that emits light of a green wavelength is disposed, and a blue sub-pixel in which the light-emitting element ED3 that emits light of a blue wavelength is disposed. The plurality of pixels PXL may further include a white sub-pixel.

Referring to FIGS. 2 and 3, the plurality of pixels PXL may be repeatedly arranged in a first direction (X-axis direction) and a second direction (Y-axis direction) intersecting the first direction. A plurality of sub-pixels having the same color may be arranged within each pixel in the display area AA. For example, each of the plurality of pixels PXL may include a first red sub-pixel in which a first-first light-emitting element ED1-1 that emits light of a red wavelength is positioned, a second red sub-pixel in which a first-second light-emitting element ED1-2 that emits light of a red wavelength is positioned, a first green sub-pixel in which a second-first light-emitting element ED2-1 that emits light of a green wavelength is positioned, a second green sub-pixel in which a second-second light-emitting element ED2-2 that emits light of a green wavelength is positioned, a first blue sub-pixel in which a third-first light-emitting element ED3-1 that emits light of a blue wavelength is positioned, and a second blue sub-pixel in which a third-second light-emitting element ED3-2 that emits light of a blue wavelength is positioned. The first-first light-emitting element ED1-1, the second-first light-emitting element ED2-1, and the third-first light-emitting element ED3-1 may be interpreted as main light-emitting elements. The first-second light-emitting element ED1-2, the second-second light-emitting element ED2-2, and the third-second light-emitting element ED3-2 may be interpreted as sub-light-emitting elements.

One sub-pixel may include one or more light-emitting elements, and when one of the light-emitting elements is defective, the luminance of another light-emitting element may be increased to adjust the luminance of the sub-pixel. However, the present disclosure is not necessarily limited thereto, and one sub-pixel may include only one light-emitting element.

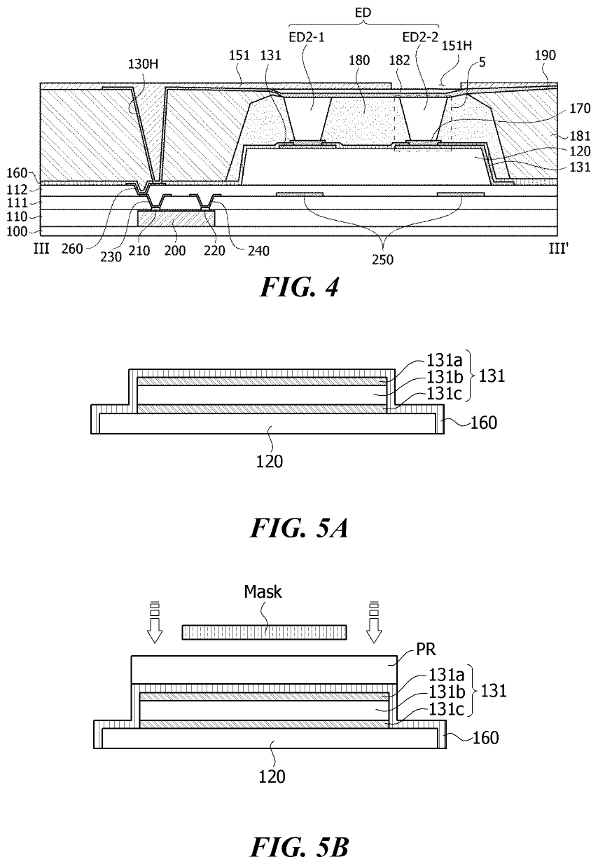

A plurality of sub-pixels may include a plurality of first connection electrodes 131 (referring to FIG. 4) extending in the first direction (X-axis direction), and may be positioned between the plurality of first connection electrode 131 respectively. The plurality of first connection electrodes 131 may be respectively positioned below light-emitting elements ED, and may be selectively connected to a plurality of signal wires TL1 to TL6 through extensions. A high potential voltage may be applied to a pixel driving circuit through the signal wires TL1 to TL6. The signal wire TL1 to TL6 and the first connection electrode 131 may be formed as an integrated electrode pattern in an electrode patterning process.

For example, a first signal wire TL1 may be connected to the connection electrode of the first red sub-pixel, and a second signal wire TL2 may be connected to the connection electrode of the second red sub-pixel. A third signal wire TL3 may be connected to the connection electrode of the first green sub-pixel, and a fourth signal wire TL4 may be connected to the connection electrode of the second green sub-pixel. A fifth signal wire TL5 may be connected to the connection electrode of the first blue sub-pixel, and a sixth signal wire TL6 may be connected to the connection electrode of the second blue sub-pixel. If one sub-pixel includes only one light-emitting element, the number of signal wires TL may be reduced by half.

A second electrode 190 may be a cathode electrode that is arranged for each row and applies a high potential voltage to the light-emitting elements ED that are repeatedly arranged in the first direction (X-axis direction). The plurality of second electrodes 190 may be spaced apart from each other in the second direction (Y-axis direction). The plurality of second electrodes 190 may be connected to a high potential voltage through a contact electrode 260. Each of the plurality of second electrodes 190 may be electrically connected to the contact electrode 260. However, the present disclosure is not necessarily limited thereto, and the second electrode 190 may be composed of one electrode layer to function as a common electrode without being divided into a plurality of electrodes.

FIG. 4 is a cross-sectional view taken along line 4-4′ in FIG. 3. Referring to FIG. 4, the display device according to an embodiment includes a pixel driving circuit 200 positioned on a substrate 100, a plurality of connection wires 230, 240, and 250, at least one insulating layer 111 and 112, and the plurality of light-emitting elements ED positioned above the at least one insulating layer 111 and 112. The at least one insulating layer 111 and 112 may be positioned on the pixel driving circuit 200. A protrusion may be positioned on the at least one insulating layer. The first connection electrode 131 and the light-emitting element ED may be positioned on the protrusion. The first connection electrode 131 may be configured to connect the light-emitting element ED to the pixel driving circuit 200.

The substrate 100 may be made of a plastic having flexibility. For example, the substrate 100 may be manufactured as a single-layer or multi-layer substrate made of a material selected from polyimide, polyethylene terephthalate, polyethylene naphthalate, polycarbonate, polyethersulfone, polyarylate, polysulfone, and cyclic olefin copolymer, but is not limited thereto. For example, the substrate 100 may be a ceramic substrate or a glass substrate.

The substrate 100 may include the display area AA and the non-display area NA. The pixel driving circuit 200 (or, referred to as a driver) may be positioned in the display area AA of the substrate 100. A plurality of pixels may be connected to the pixel driving circuit 200. The pixel driving circuit 200 may include a plurality of thin film transistors using an amorphous silicon semiconductor, a polycrystalline silicon semiconductor, or an oxide semiconductor.

The pixel driving circuit 200 may include at least one driving thin film transistor, at least one switching thin film transistor, and at least one storage capacitor.

When the pixel driving circuit 200 includes a plurality of thin film transistors, it may be formed on the substrate 100 by a thin film transistor (TFT) manufacturing process. In an embodiment, the pixel driving circuit 200 may collectively refer to a plurality of thin film transistors electrically connected to the light-emitting element ED.

The pixel driving circuit 200 may be a driving driver manufactured using a metal-oxide-silicon field effect transistor (MOSFET) manufacturing process on a single crystal semiconductor substrate. The driving driver may include a plurality of pixel driving circuits to drive a plurality of sub-pixels. When the pixel driving circuit 200 is implemented as a driving driver, the driving driver may be mounted on an adhesive layer by a transfer process after the adhesive layer is positioned on the substrate 100.

A buffer layer 110 may be positioned on the substrate 100 to surround the pixel driving circuit 200 and cover at least a portion of the pixel driving circuit 200. The buffer layer 110 may contain an organic insulating material, e.g., photosensitive photoacryl or photosensitive polyimide, but is not limited thereto.

The buffer layer 110 may be formed by stacking an inorganic insulating material, e.g., silicon nitride (SiNx) or silicon oxide (SiO2), in multiple layers, or by stacking an organic insulating material and an inorganic insulating material in multiple layers.

The pixel driving circuit 200 may include a plurality of contact electrodes. The buffer layer 110 may have openings that expose the plurality of contact electrodes of the pixel driving circuit 200. A first contact electrode 210 and a second contact electrode 220 of the pixel driving circuit 200 may be exposed through the openings of the buffer layer 110.

A first insulating layer 111 may be positioned on the buffer layer 110. The first insulating layer 111 may contain an organic insulating material, e.g., photosensitive photoacryl or photosensitive polyimide, but is not limited thereto. A first connection wire 230, a second connection wire 240, and a third connection wire 250 may be positioned on the first insulating layer 111. The first connection wire 230, the second connection wire 240, and the third connection wire 250 may transmit signals of the first contact electrode 210 and the second contact electrode 220 of the pixel driving circuit 200 to the signal wires TL1 to TL6.

The first connection wire 230, the second connection wire 240, and the third connection wire 250 may include a plurality of wire patterns positioned in different layers with one or more insulating layers interposed between the wire patterns. The wire patterns positioned in different layers may be electrically connected to each other through contact holes penetrating the insulating layer.

A second insulating layer 112 may be positioned on the first insulating layer 111, the first connection wire 230, the second connection wire 240, and the third connection wire 250. The second insulating layer 112 may contain an organic insulating material, e.g., photosensitive photoacryl or photosensitive polyimide, but is not limited thereto.

The second connection electrode 260 and the first connection electrode 131 may be positioned on the second insulating layer 112.

The second connection electrode 260 may be electrically connected to the pixel driving circuit 200 and transmit a high potential voltage to the light-emitting element ED.

A plurality of bank patterns 120 may be positioned on the second insulating layer 112. At least one light-emitting element ED may be positioned on each bank pattern 120.

The bank pattern 120 may contain an organic insulating material, e.g., photosensitive photoacryl or photosensitive polyimide, but is not limited thereto. The bank pattern 120 may guide a position to which the light-emitting element ED is to be attached in the transfer process of the light-emitting element ED.

The first connection electrode 131 may be positioned on the second insulating layer 112 and the bank pattern 120. The first connection electrode 131 may be formed by the same process as the signal wires TL1 to TL6 and may extend from the signal wires TL1 to TL6 to a region on the bank pattern 120 where the light-emitting element ED is positioned.

A protective layer 160 may be positioned on the first connection electrode 131 and the second insulating layer 112. The protective layer 160 may be formed by stacking an inorganic insulating material, e.g., silicon nitride (SiNx) or silicon oxide (SiO2), in multiple layers, or by stacking an organic insulating material and an inorganic insulating material in multiple layers.

The protective layer 160 may have an opening that exposes a portion of the first connection electrode 131.

An adhesive layer 170 may be formed in the opening of the protective layer 160. The adhesive layer 170 may contain indium (In), tin (Sn), gold (Au), or an alloy thereof, but is not limited thereto.

The light-emitting elements ED may be transferred to correspond to the adhesive layer 170. One pixel PXL may include the light-emitting elements ED of three colors. A first light-emitting element may be a red light-emitting element, a second light-emitting element may be a green light-emitting element, and a third light-emitting element may be a blue light-emitting element. Two light-emitting elements may be mounted in each sub-pixel.

Two or more light-emitting elements ED of the same color may be arranged on the bank pattern 120, so that one pixel PXL may include at least six light-emitting elements ED.

A transfer method is not particularly limited. That is, the light-emitting element ED grown on a semiconductor growth substrate may be primarily transferred to a transfer substrate, and then may be secondarily transferred to the panel substrate 100, or the light-emitting element ED grown on the semiconductor growth substrate may be directly transferred to the panel substrate.

A third insulating layer 180 may be positioned to surround the light-emitting element ED and the bank pattern 120.

The third insulating layer 180 may cover the bank pattern 120 and the side surface and a portion of the top surface of the light-emitting element ED. The third insulating layer 180 may cover spaces between the plurality of light-emitting elements ED and spaces between the plurality of bank patterns 120. The third insulating layer 180 may extend in the first direction (X-axis direction) and be separated with a spacing in the second direction (Y-axis direction) between rows of the pixels PXL.

The third insulating layer 180 may contain an organic insulating material in which fine metal particles such as titanium dioxide particles are dispersed. Light emitted from the plurality of light-emitting elements ED may be scattered and diffused by the fine metal particles dispersed in the third insulating layer 180 and emitted to the outside.

A fourth insulating layer 181 may be positioned on the third insulating layer 180 and the protective layer 160. The fourth insulating layer 181 may contain an organic insulation material surrounding the third insulating layer 180. The fourth insulating layer 181 may be positioned on the protective layer 160 together with the third insulating layer 180. The third insulating layer 180 and the fourth insulating layer 181 may contain the same material (e.g., siloxane).

For example, the third insulating layer 180 may be a siloxane that does not contain titanium oxide (TiOx). However, the present disclosure is not limited thereto, and the third insulating layer 180 and the fourth insulating layer 181 may contain the same material or different materials.

The third insulating layer 180 may have an opening that exposes the upper portion of the light-emitting element ED. An electrode of the light-emitting element ED positioned on the upper portion of the light-emitting element ED may be exposed to be connected to the second electrode 190.

The second electrode 190 may be positioned on the plurality of light-emitting elements ED. The second electrode 190 may be connected in common to the plurality of pixels PXL. The second electrode 190 may be a thin electrode through which light is transmitted. The second electrode 190 may contain a transparent electrode material, e.g., indium tin oxide (ITO), but is not necessarily limited thereto.

The second electrode 190 may extend in the first direction (X-axis direction) and be separated in the second direction (Y-axis direction). The second electrode 190 may be positioned on the top surface of the light-emitting element ED, the top surface of the third insulating layer 180, and the fourth insulating layer 181, and may be in contact with the second connection electrode 260 through a connection electrode contact hole 130H formed in the fourth insulating layer 181.

A fifth insulating layer 182 may be positioned on the second electrode 190 overlapping the light-emitting element ED and the bank pattern 120. The fifth insulating layer 182 may contain the same material as the third insulating layer 180.

After the opening for exposing the upper electrode of the light-emitting element ED is formed in the third insulating layer 180 and the second electrode 190 is positioned, the fifth insulating layer 182 may be positioned to planarize the corresponding region and improve the light efficiency of the light-emitting element ED.

A light blocking layer 151 may be positioned on the fifth insulating layer 182 and the second electrode 190.

The light blocking layer 151 may contain an organic insulating material to which a black pigment is added. The light blocking layer 151 may fill the connection electrode contact hole 130H and the top surface of the light blocking layer 151 may be planarized. A transmission hole 151H through which light from the light-emitting element ED is emitted to the outside may be formed between patterns of the light blocking layer 151. The light blocking layer 151 may improve the problem in which light emitted from adjacent light-emitting elements ED is mixed.

The light blocking layer 151 may cover the upper portion of the second-first light-emitting element ED2-1, among the second-first light-emitting element ED2-1 and the second-second light-emitting element ED2-2 that emit light of the same color positioned on the bank pattern 120.

Among the light-emitting elements ED that emit light of the same color in one pixel PXL, one light-emitting element (e.g., the second-first light-emitting element ED2-1) may be defective, may not be transferred onto the substrate 100, or may not operate due to a transfer defect. In this case, the second-first light-emitting element ED2-1 may be covered and blocked by the light blocking layer 151, and the transmission hole 151H may be formed above the second-second light-emitting element ED2-2 to allow light to be emitted to the outside.

The light blocking layer 151 may be formed over the entire surface of the substrate 100, and the transmission hole 151H may be formed only on the light-emitting elements ED in which no defect has occurred in the pixel PXL.

Even when the light-emitting elements ED that emit light of the same color in the pixel PXL are all normal, the transmission hole 151H may be formed only above one of the light-emitting elements ED.

An encapsulation layer and a cover glass may be positioned on the light blocking layer 151, or a color filter may also be positioned.

Hereinafter, a method for manufacturing a display device according to one embodiment of the present disclosure will be described with reference to the drawings.

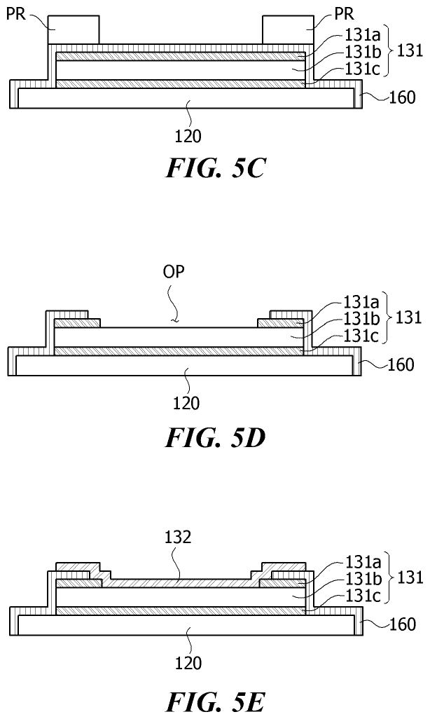

FIGS. 5A to 5F are cross-sectional views illustrating manufacturing processes of a region 5 in FIG. 4.

Referring to FIG. 5A, the first connection electrode 131 may be positioned on the bank pattern 120.

The first connection electrode 131 may include a first metal layer 131a, a second metal layer 131b, and a third metal layer 131c. The first connection electrode 131 may include a reflective region, which will be further described below.

The first metal layer 131a and the third metal layer 131c may contain titanium (Ti) or molybdenum (Mo). The second metal layer 131b may contain aluminum (Al).

The protective layer 160 may be formed on the bank pattern 120 and the first connection electrode 131.

Referring to FIGS. 5B and 5C, after forming the protective layer 160, a process for exposing a portion of the first connection electrode 131 may be performed. Next, a photosensitive resin PR may be applied onto the protective layer 160. The photosensitive resin PR may be an organic compound in which a light-reactive material is mixed.

Subsequently, a mask pattern may be positioned above the portion of the photosensitive resin PR located in an electrode opening formation region for exposing the first connection electrode 131, and light may be irradiated onto the photosensitive resin PR. Then, a region of the photosensitive resin PR other than the portion exposed to light may be removed through a stripping process. Thereafter, the protective layer 160 and the first metal layer 131a may be removed through an etching process.

Referring to FIG. 5D, using the remaining photosensitive resin PR as an etching mask, the protective layer 160 made of an inorganic insulating material and the first metal layer 131a made of a metal material may be simultaneously etched and removed to form an electrode opening OP that exposes the second metal layer 131b. In this case, due to the difference in etching rates between the protective layer 160 and the first metal layer 131a, the protective layer 160 may be etched more than the first metal layer 131a during the etching process.

As a result, a step difference between the protective layer 160 and the first metal layer 131a may occur in the electrode opening OP where the second metal layer 131b is exposed.

The second metal layer 131b may contain a metal material having high reflectivity, such as aluminum (Al), silver (Ag), or copper (Cu) as the reflective layer. A reflective region that reflects light emitted from the light-emitting element ED upward through the electrode opening OP and emits it to the outside may be formed in the second metal layer 131b. That is, the reflective region is a region of the second metal layer 131b that is exposed by the electrode opening OP. The reflective region overlaps a region in which the light-emitting element ED of the pixel is positioned.

Referring to FIG. 5E, the remaining photosensitive resin PR may be removed, and the first electrode 132 may be positioned in the electrode opening OP. The first electrode 132 may be positioned in the electrode opening OP and on portions of the first metal layer 131a and the protective layer 160 having the step difference.

The first electrode 132 may contain a transparent conductive oxide, such as indium tin oxide (ITO) or indium zinc oxide (IZO), which has good adhesion to a first adhesive layer 133 and exhibits corrosion resistance and acid resistance.

Referring to FIG. 5F, the first adhesive layer 133 may be positioned on the first electrode 132. The first adhesive layer 133 may be positioned in the electrode opening OP and formed with a smaller area than the first electrode 132. That is, the first adhesive layer 133 may be positioned on the first electrode 132 in the reflective region. The first adhesive layer 133 may contain a metal material, such as indium (In), tin (Sn), or an alloy thereof, but is not limited thereto.

Subsequently, the light-emitting element ED may be positioned on the first adhesive layer 133. The light-emitting element ED may be transferred from a semiconductor substrate or a transfer substrate onto the substrate 100 through a transfer process. As shown in FIG. 5F, the first electrode 132 may be positioned between the light-emitting element ED and the first connection electrode 131. A transfer substrate on which a plurality of light-emitting elements ED are arranged may be aligned above the substrate 100, to transfer the plurality of light-emitting elements ED onto the first adhesive layer 133. The plurality of light-emitting elements ED arranged on the transfer substrate may be light-emitting elements ED that emit light of the same color.

At this time, if there is a misalignment between the substrate 100 and the transfer substrate, the light-emitting element ED may be positioned with some deviation from a selected location.

When the first adhesive layer 133 is formed with a larger area than the bottom surface of the light-emitting element ED, the light-emitting element ED may still be normally transferred even if it is positioned with some deviation.

The light-emitting element ED may be transferred in a state in which a second adhesive layer 134 is positioned therebelow. The second adhesive layer 134 may contain a metal material, such as gold (Au) or silver (Ag), which is capable of eutectic bonding with the first adhesive layer 133.

The first adhesive layer 133 and the second adhesive layer 134 may be bonded by eutectic bonding at a temperature of 140° C. to 170° C.

The adhesive layer 170 may include the first electrode 132, the first adhesive layer 133, and the second adhesive layer 134. Areas of the first electrode 132, the first adhesive layer 133, and the second adhesive layer 134 are different from each other.

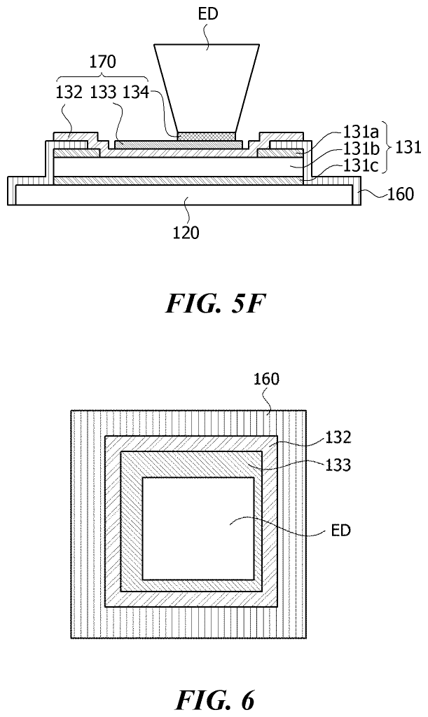

FIG. 6 is a plan view of a region of a pixel PXL in FIG. 4. Referring to FIG. 6, even if the light-emitting element ED is transferred with some deviation, it may still be positioned on the first connection electrode 131. Referring to FIG. 5F, the protective layer 160 may be positioned between an end of the first electrode 132 and the first connection electrode 131 and may be in contact with the side surface of the first connection electrode 131. Accordingly, the side surface of the second metal layer 131b may be protected during the photolithography and etching processes for forming the electrode opening OP.

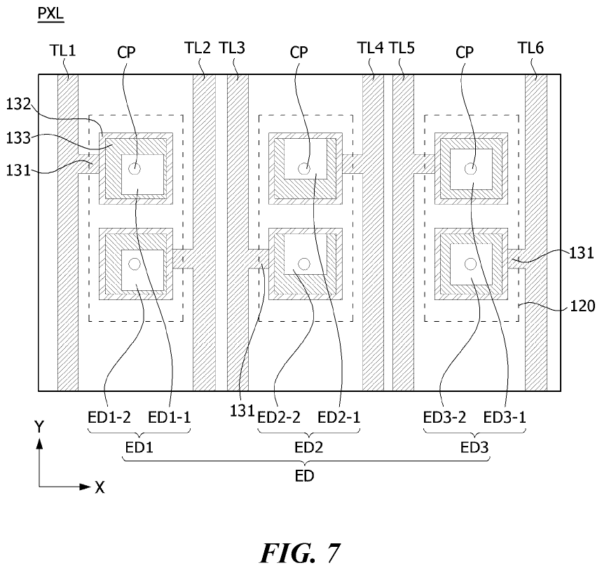

FIG. 7 is a schematic plan view of a pixel PXL formed according to an embodiment of the present disclosure. Referring to FIG. 7, the light-emitting elements ED in the pixel PXL may be positioned at different locations on the bank pattern 120 for each sub-pixel.

The light-emitting element ED of each sub-pixel may be positioned on the first adhesive layer 133 formed on the first electrode 132, and may be positioned at different locations in the first direction or in the second direction intersecting the first direction with respect to a central point CP of the first adhesive layer 133. For example, the red light-emitting element ED1, the green light-emitting element ED2, and the blue light-emitting element ED3 may be transferred to different locations with respect to a central point CP.

The red light-emitting element EDI may include the first-first light-emitting element ED1-1 and the first-second light-emitting element ED1-2, and since the first-first light-emitting element ED1-1 and the first-second light-emitting element ED1-2 may be transferred simultaneously, they may be arranged to be equally spaced in the first direction (X-axis direction) and the second direction (Y-axis direction) from the central point CP of the first adhesive layer 133.

The green light-emitting element ED2 may include the second-first light-emitting element ED2-1 and the second-second light-emitting element ED2-2, and since the second-first light-emitting element ED2-1 and the second-second light-emitting element ED2-2 are transferred simultaneously, they may be arranged to be equally spaced in the first direction (X-axis direction) and the second direction (Y-axis direction) from the central point CP of the first adhesive layer 133.

The blue light-emitting element ED3 may include the third-first light-emitting element ED3-1 and the third-second light-emitting element ED3-2, and since the third-first light-emitting element ED3-1 and the third-second light-emitting element ED3-2 are transferred simultaneously, they may be arranged to be equally spaced in the first direction (X-axis direction) and the second direction (Y-axis direction) from the central point CP of the first adhesive layer 133.

When the red light-emitting element ED1, the green light-emitting element ED2, and the blue light-emitting element ED3 are simultaneously transferred using the same transfer substrate, the light-emitting elements ED that are arranged on the same transfer substrate and transferred onto the substrate 100 may be transferred to the same location from the central point CP in the first direction X and the second direction Y, but the present disclosure is not limited thereto.

The display device according to various embodiments of the present disclosure may be described as follows.

A display device according to one embodiment of the present disclosure may comprise a substrate including a display area and a non-display area; a driver positioned in the display area; a plurality of pixels connected to the driver, each of the plurality of pixels including a plurality of sub-pixels; a light-emitting element positioned in an emission area of the sub-pixel; a connection electrode configured to connect the light-emitting element to the driver; a first electrode positioned between the light-emitting element and the connection electrode; and a protective layer positioned between one end of the first electrode and the connection electrode.

According to one embodiment of the present disclosure, the connection electrode may include plurality of metal layers, and the connection electrode includes a reflective region.

According to one embodiment of the present disclosure, the reflective region may be a region in which a metal layer containing a reflective material among the plurality of metal layers is exposed.

According to one embodiment of the present disclosure, the plurality of metal layers may contain at least one of titanium (Ti), indium tin oxide (ITO), aluminum (Al), copper (Cu), gold (Au), and indium zinc oxide (IZO).

According to one embodiment of the present disclosure, the display device may further comprise a first adhesive layer positioned on the first electrode.

According to one embodiment of the present disclosure, the display device may further comprise a second adhesive layer positioned below the light-emitting element.

According to one embodiment of the present disclosure, the first adhesive layer and the second adhesive layer may contain a metal material.

According to one embodiment of the present disclosure, the first adhesive layer and the second adhesive layer may be bonded by eutectic bonding.

According to one embodiment of the present disclosure, the areas of the first electrode, the first adhesive layer, and the second adhesive layer may be different from each other.

According to one embodiment of the present disclosure, at least one insulating layer may be positioned on the driver, a protrusion is positioned on the insulating layer, and the connection electrode and the light-emitting element are positioned on the protrusion.

According to one embodiment of the present disclosure, the plurality of sub-pixels may include a plurality of connection electrode extending in a first direction, and include a first sub-pixel, a second sub-pixel, and a third sub-pixel respectively positioned between the plurality of connection electrode.

According to one embodiment of the present disclosure, the light-emitting element of the first sub-pixel, the light-emitting element of the second sub-pixel, and the light-emitting element of the third sub-pixel may be positioned on an adhesive layer formed on the first electrode, and be positioned at different locations in a first direction or in a second direction intersecting the first direction with respect to a central point of the adhesive layer.

According to one embodiment of the present disclosure, each of the first sub-pixel, the second sub-pixel, and the third sub-pixel may include at least two light-emitting elements.

According to one embodiment of the present disclosure, the protective layer may be in contact with an upper surface of an end of the connection electrode and a side surface of the connection electrode.

A method for manufacturing a display device according to one embodiment of the present disclosure may comprise positioning a driver in a display area including a plurality of pixels on a substrate; positioning a first insulating layer on the driver; forming, on the first insulating layer, a connection electrode connected to the driver and including a plurality of metal layers and a reflective layer; forming a reflective region by removing at least one layer among the plurality of metal layers of the connection electrode to expose the reflective layer; positioning a protective layer on the connection electrode and the first insulating layer; forming an opening in the protective layer to expose the reflective region; and positioning a first electrode in the reflective region.

According to one embodiment of the present disclosure, the reflective region may overlap a region in which a light-emitting element of the pixel is positioned.

According to one embodiment of the present disclosure, an end of the first electrode may be positioned on the protective layer.

According to one embodiment of the present disclosure, the display device may further comprise positioning a first adhesive layer on the first electrode in the reflective region.

According to one embodiment of the present disclosure, the display device may further comprise aligning, above the substrate, a transfer substrate on which a plurality of light-emitting elements is arranged, and transferring the plurality of light-emitting elements onto the first adhesive layer.

According to one embodiment of the present disclosure, the plurality of light-emitting elements arranged on the transfer substrate may be light-emitting elements that emit light of the same color.

According to one embodiment of the present disclosure, the second adhesive layer may be formed on one surface of the plurality of light-emitting elements.

Although embodiments of the present disclosure have been described in more detail with reference to the accompanying drawings, the present disclosure is not necessarily limited to the embodiments, and various modifications may be carried out without departing from the technical spirit of the present disclosure.

Therefore, the embodiments disclosed in the present disclosure are not intended to limited the technical spirit of the present disclosure, but intended to describe the same, and the scope of the technical spirit of the present disclosure is not limited by these embodiments. Therefore, it should be understood that the above-described embodiments are illustrative and not restrictive in all respects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area and a non-display area;
a driver positioned in the display area;
a plurality of pixels connected to the driver, each of the plurality of pixels including a plurality of sub-pixels;
a light-emitting element positioned in a sub-pixel;
a connection electrode configured to connect the light-emitting element to the driver;
a first electrode between the light-emitting element and the connection electrode; and
a protective layer between an end of the first electrode and the connection electrode.

2. The display device of claim 1, wherein the connection electrode includes a plurality of metal layers, and the connection electrode includes a reflective region.

3. The display device of claim 2, wherein the reflective region is a region in which a metal layer containing a reflective material among the plurality of metal layers is exposed.

4. The display device of claim 2, wherein the plurality of metal layers contains at least one of titanium, indium tin oxide, aluminum, copper, gold, and indium zinc oxide.

5. The display device of claim 1, further comprising:
a first adhesive layer on the first electrode.

6. The display device of claim 5, further comprising:
a second adhesive layer positioned below the light-emitting element.

7. The display device of claim 6, wherein the first adhesive layer and the second adhesive layer contain a metal material.

8. The display device of claim 6, wherein the first adhesive layer and the second adhesive layer are bonded by eutectic bonding.

9. The display device of claim 6, wherein the first electrode, the first adhesive layer, and the second adhesive layer each have a different area.

10. The display device of claim 1, wherein at least one insulating layer is on the driver, a protrusion is on the at least one insulating layer, and the connection electrode and the light-emitting element are on the protrusion.

11. The display device of claim 1, wherein the plurality of sub-pixels includes a plurality of connection electrodes extending in a first direction, and include a first sub-pixel, a second sub-pixel, and a third sub-pixel respectively positioned between the plurality of connection electrode.

12. The display device of claim 11, wherein the light-emitting element of the first sub-pixel, the light-emitting element of the second sub-pixel, and the light-emitting element of the third sub-pixel are positioned on an adhesive layer formed on the first electrode, and are positioned at different locations in a first direction or in a second direction transverse to the first direction with respect to a central point of the adhesive layer.

13. The display device of claim 11, wherein each of the first sub-pixel, the second sub-pixel, and the third sub-pixel includes at least two light-emitting elements.

14. The display device of claim 11, wherein the protective layer is in contact with an upper surface of an end of the connection electrode and a side surface of the connection electrode.

15. A method for manufacturing a display device, comprising:
positioning a driver in a display area including a plurality of pixels on a substrate;
positioning a first insulating layer on the driver;
forming, on the first insulating layer, a connection electrode connected to the driver and including a plurality of metal layers and a reflective layer;
forming a reflective region by removing at least one layer among the plurality of metal layers of the connection electrode to expose the reflective layer;
positioning a protective layer on the connection electrode and the first insulating layer;
forming an opening in the protective layer to expose the reflective region; and
positioning a first electrode in the reflective region.

16. The method for manufacturing a display device of claim 15, wherein the reflective region overlaps a region in which a light-emitting element of the pixel is positioned.

17. The method for manufacturing a display device of claim 16, wherein an end of the first electrode is on the protective layer.

18. The method for manufacturing a display device of claim 15, further comprising:
positioning a first adhesive layer on the first electrode in the reflective region.

19. The method for manufacturing a display device of claim 18, further comprising:
aligning, above the substrate, a transfer substrate on which a plurality of light-emitting elements is arranged, and transferring the plurality of light-emitting elements onto the first adhesive layer.

20. The method for manufacturing a display device of claim 19, wherein the plurality of light-emitting elements arranged on the transfer substrate are light-emitting elements that emit light of a same color.

21. The method for manufacturing a display device of claim 19, further comprising:
forming a second adhesive layer on one surface of the plurality of light-emitting elements.

22. The display device of claim 1, further comprising a light blocking layer having a transmission hole on the light-emitting element and emitting light from the light-emitting element to the outside through the transmission hole.
